(19) United States
(12) Patent Application Publication
(10) Pub. No.: US 2025/0194157 A1
(43) Pub. Date: Jun. 12, 2025

(54) SEMICONDUCTOR DEVICE, MANUFACTURING METHOD THEREFOR, AND ELECTRONIC APPARATUS

(71) Applicant: CXMT Corporation, Hefei City (CN)

(72) Inventors: Jinying LIU, Hefei City (CN); Xingkun XUE, Hefei City (CN); Di MA, Hefei City (CN)

(73) Assignee: CXMT Corporation, Hefei City (CN)

(21) Appl. No.: 18/942,636

(22) Filed: Nov. 9, 2024

Related U.S. Application Data
(63) Continuation of application No. PCT/CN2024/110093, filed on Aug. 6, 2024.

(30) Foreign Application Priority Data
Dec. 11, 2023 (CN) 202311698246.6

(51) Int. Cl. H01L 29/423; H01L 29/49; H10B 12/00

(52) U.S. Cl. CPC H10D 30/6735; H10B 12/05; H10D 64/666

(57) ABSTRACT

A semiconductor device, a manufacturing method therefor, and an electronic apparatus are provided. The semiconductor device includes at least one transistor, where each transistor includes a first source/drain, a second source/drain, a channel region, and a gate structure. The channel region is located between the first source/drain and the second source/drain. The gate structure includes a gate dielectric layer in contact with the channel region, a gate conductive layer, and a first threshold voltage regulating layer located between the gate dielectric layer and the gate dielectric layer, where the first threshold voltage regulating layer is configured to regulate a threshold voltage of the transistor. The embodiments of the present disclosure can improve the electrical properties of the semiconductor device.

### CROSS-REFERENCE TO RELATED APPLICATIONS

This is a continuation of International Patent Application No. PCT/CN2024/110093, filed on Aug. 6, 2024, which claims priority to Chinese Patent Application No. 202311698246.6 filed on Dec. 11, 2023. The disclosures of the above-referenced applications are hereby incorporated by reference in their entirety.

### BACKGROUND

As the integration density of memories becomes increasingly higher, higher requirements are placed on the arrangement mode and size of transistors in the array structure of memories.

At present, the structure of the memory remains to be further improved.

### SUMMARY

Embodiments of the present disclosure relate to the technical field of semiconductors, in particular to a semiconductor device, a manufacturing method therefor, and an electronic apparatus.

In view of this, embodiments of the present disclosure provide a semiconductor device, a manufacturing method therefor, and an electronic apparatus.

To achieve the above-mentioned objectives, the technical solutions of the present disclosure are realized as follows:

In a first aspect, the embodiments of the present disclosure provide a semiconductor device. The semiconductor device includes at least one transistor. Each transistor includes a first source/drain, a second source/drain, a channel region, and a gate structure. The channel region is located between the first source/drain and the second source/drain, and the gate structure includes a gate dielectric layer, a gate conductive layer, and a first threshold voltage regulating layer located between the gate dielectric layer and the gate conductive layer, where the gate dielectric layer is in contact with the channel region, and the first threshold voltage regulating layer is configured to regulate a threshold voltage of the transistor.

In a second aspect, the embodiments of the present disclosure provide a method for manufacturing a semiconductor device. The semiconductor device includes at least one transistor, and the method includes: providing at least one transistor pillar, where each transistor pillar includes, in sequence along an extension direction, a first source/drain, a channel region, and a second source/drain; forming a gate dielectric layer covering at least one sidewall of the transistor pillar; forming a first metal material layer covering the gate dielectric layer; oxidizing the first metal material layer to form a first threshold voltage regulating layer; and forming a gate conductive layer covering the first threshold voltage regulating layer, where the first threshold voltage regulating layer is configured to regulate a threshold voltage of the transistor.

In a third aspect, the embodiments of the present disclosure provide an electronic apparatus. The electronic apparatus includes a processing device and a semiconductor device electrically connected to the processing device. The semiconductor device includes at least one transistor. Each transistor includes a first source/drain, a second source/drain, a channel region, and a gate structure. The channel region is located between the first source/drain and the second source/drain, and the gate structure includes a gate dielectric layer, a gate conductive layer, and a first threshold voltage regulating layer located between the gate dielectric layer and the gate conductive layer, where the gate dielectric layer is in contact with the channel region, and the first threshold voltage regulating layer is configured to regulate a threshold voltage of the transistor.

### BRIEF DESCRIPTION OF THE DRAWINGS

FIG. 1 is a schematic cross-sectional structure diagram of a semiconductor device provided according to an example;

FIG. 2 is a schematic cross-sectional structure diagram of a semiconductor device provided according to another example;

FIG. 3 is a schematic cross-sectional structure diagram of a semiconductor device provided according to still another example;

FIG. 4 is a schematic top-view structure diagram of a semiconductor device provided according to still another example;

FIG. 5 is a schematic flow chart of a method for manufacturing a semiconductor device provided according to the embodiments of the present disclosure;

FIG. 6A is a first schematic top-view structure diagram of a semiconductor device provided according to the embodiments of the present disclosure during a manufacturing process.

FIG. 6B is a second schematic top-view structure diagram of a semiconductor device provided according to the embodiments of the present disclosure during a manufacturing process.

FIG. 6C is a third schematic top-view structure diagram of a semiconductor device provided according to the embodiments of the present disclosure during a manufacturing process.

FIG. 6D is a fourth schematic top-view structure diagram of a semiconductor device provided according to the embodiments of the present disclosure during a manufacturing process.

FIG. 6E is a fifth schematic top-view structure diagram of a semiconductor device provided according to the embodiments of the present disclosure during a manufacturing process.

FIG. 7 is a schematic cross-sectional structure diagram of a semiconductor device provided according to the embodiments of the present disclosure during a manufacturing process.

FIG. 8 is a schematic structure diagram of an electronic apparatus illustrated according to the embodiments of the present disclosure.

### DETAILED DESCRIPTION

The technical solutions in embodiments of the present disclosure will be clearly and completely described below with reference to the embodiments of the present disclosure and the drawings. It is obvious that the described embodiments are only part of the embodiments of the present disclosure rather than all embodiments. Based on the embodiments of the present disclosure, all other embodiments obtained by those skilled in the art without creative work shall fall within the protection scope of the present disclosure.

In the following description, numerous specific details are set forth in order to provide a more thorough understanding of the present disclosure. However, it will be apparent to those skilled in the art that the present disclosure may be practiced without one or more of these specific details. In other instances, some well-known technical features in the art are not described to avoid confusion with the present disclosure; i.e., not all features of the actual embodiments are described herein, and well-known functions and structures are not described in detail.

In the drawings, the dimensions of layers, regions, and elements, and their relative dimensions may be exaggerated for clarity. Identical reference numerals represent identical elements throughout the text.

It should be appreciated that when an element or a layer is referred to as being “on”, “adjacent to”, “connected to”, or “coupled to” another element or layer, it may be directly on, adjacent to, connected to, or coupled to the another element or layer, or an intervening element or layer may be present. On the contrary, when an element is referred to as being “directly on”, “directly adjacent to”, “directly connected to”, or “directly coupled to” another element or layer, no intervening element or layer is present. It should be appreciated that, although the terms first, second, third, etc., may be used to describe various elements, components, regions, layers, and/or portions, the elements, components, regions, layers, and/or portions should not be limited by these terms. These terms are only used to distinguish one element, component, region, layer, or portion from another element, component, region, layer, or portion. Therefore, a first element, component, region, layer, or portion discussed below may be termed a second element, component, region, layer, or portion without departing from the teachings of the present disclosure. However, the discussion of a second element, component, region, layer, or portion does not necessarily imply that a first element, component, region, layer, or portion is necessarily present in the present disclosure.

Spatial relationship terms, e.g., “under”, “below”, “underneath”, “beneath”, “on”, “above”, and the like, may be used herein for ease of description to describe the relationship between an element or a feature shown in the figures and other elements or features. It should be appreciated that the spatial relationship terms are intended to encompass different orientations of the device in use or operation in addition to the orientations depicted in the figures. For example, if the device in the figures is turned over, elements or features described as being “below”, “beneath”, or “under” other elements or features would then be oriented “above” the other elements or features. Therefore, the exemplary terms “below” and “under” may include both up and down orientations. A device may be otherwise oriented (rotated 90 degrees or at other orientations) and the spatial descriptors used herein may be interpreted accordingly.

The terms used herein are for the purpose of describing specific embodiments only and should not be construed as limiting the present disclosure. As used herein, the singular forms “a”, “an”, and “the” are intended to include the plural forms as well, unless the context clearly indicates otherwise. It should be further appreciated that the terms “comprise” and/or “include”, when used in this specification, specify the presence of stated features, integers, steps, operations, elements, and/or components, but do not preclude the presence or addition of one or more other features, integers, steps, operations, elements, components, and/or groups. As used herein, the term “and/or” includes any and all combinations of the associated listed items.

In order to thoroughly understand the present disclosure, detailed steps and structures will be set forth in the following description so as to explain the technical solutions of the present disclosure. The preferred embodiments of the present disclosure are described in detail below; however, the present disclosure can be practiced otherwise than as specifically described.

As the integration density of a dynamic random access memory (DRAM) becomes increasingly higher, higher requirements are placed on the arrangement mode and size of transistors in the array structure of the DRAM. The transistor with a gate-all-around (GAA) structure serves as a transistor in a DRAM to realize a smaller size and facilitate the improvement of the integration density of the DRAM.

However, the threshold voltage of the gate-all-around transistor is low. Therefore, at present, the structure of the transistor in the memory needs to be further improved to regulate the threshold voltage of the transistor.

In view of this, the embodiments of the present disclosure provide a semiconductor device and a manufacturing method therefor.

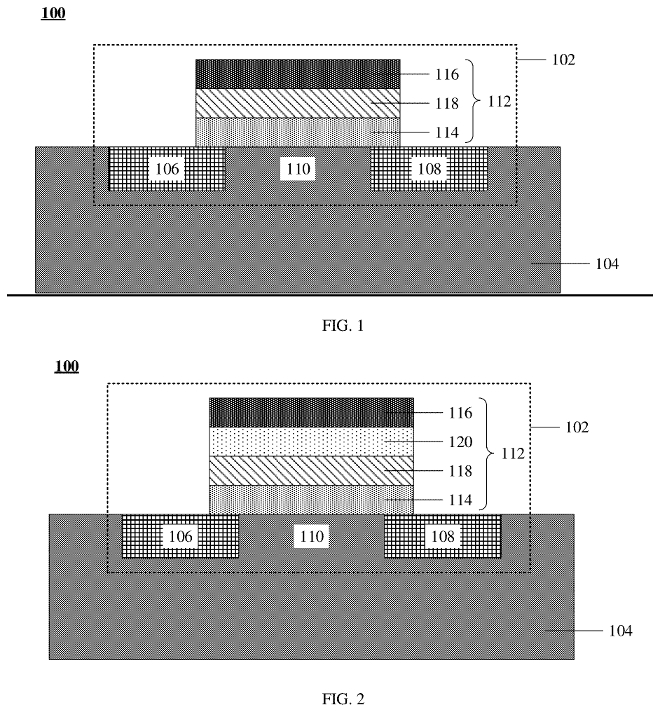

Referring to FIG. 1, FIG. 1 is a schematic cross-sectional structure diagram of a semiconductor device provided according to an example. As shown in FIG. 1, the embodiments of the present disclosure provide a semiconductor device 100. The semiconductor device 100 includes at least one transistor 102 (as shown in the dashed box in FIG. 1). Each transistor 102 includes: a first source/drain 106, a second source/drain 108, and a channel region 110 disposed in the substrate 104, where the channel region 110 is located between the first source/drain 106 and the second source/drain 108; and a gate structure 112 disposed on the substrate 104, where the gate structure 112 includes a gate dielectric layer 114, a gate conductive layer 116, and a first threshold voltage regulating layer 118 located between the gate dielectric layer 114 and the gate conductive layer 116, where the gate dielectric layer 114 is in contact with the channel region 110, and the first threshold voltage regulating layer 118 is configured to regulate a threshold voltage of the transistor 102.

In the embodiments of the present disclosure, the first threshold voltage regulating layer 118 is disposed between the gate dielectric layer 114 and the gate conductive layer 116, and a difference between work functions of the gate structure 112 and a material of the channel region 110 is increased by increasing a work function of the first threshold voltage regulating layer 118, thereby increasing the threshold voltage of the transistor 102, i.e., achieving the objective of improving electrical properties of the semiconductor device 100 by using the first threshold voltage regulating layer 118 to regulate the threshold voltage of the transistor 102.

Here, the substrate 104 may be a semiconductor substrate. The semiconductor substrate specifically includes at least one elemental semiconductor material (e.g., a silicon (Si) substrate, a germanium (Ge) substrate, and the like), at least one III-V compound semiconductor material (e.g., a gallium nitride (GaN) substrate, a gallium arsenide (GaAs) substrate, an indium phosphide (InP) substrate, and the like), at least one II-VI compound semiconductor material, at least one organic semiconductor material, or other semiconductor materials known in the art. The semiconductor substrate may further include other semiconductor material-containing substrates, e.g., a silicon-on-insulator (SOI) substrate, a germanium-on-insulator (GeOI) substrate, a polycrystalline semiconductor layer on an insulating layer, a silicon-germanium substrate, and the like.

Illustratively, the substrate 104 may be doped to form the first source/drain 106 and the second source/drain 108, where the first source/drain 106 and the second source/drain 108 serve as doped regions. Illustratively, the substrate 104 may also be doped to form the channel region 110.

In some embodiments, when the first source/drain 106 serves as a source of the transistor 102, the second source/drain 108 serves as a drain of the transistor 102. In other embodiments, when the first source/drain 106 serves as a drain of the transistor 102, the second source/drain 108 serves as a source of the transistor 102.

In some embodiments, the type of doping ions in the doped regions may be different from the type of doping ions in the channel region. For example, for a P-type metal-oxide-semiconductor field effect transistor (MOSFET), the doping ions in the doped regions are N-type ions, and the doping ions in the channel region are P-type ions, where the N-type ions may be, e.g., arsenic ions, phosphorus ions, or antimony ions, and the P-type ions may be, e.g., boron ions, indium ions, or gallium ions.

In other embodiments, the type of doping ions in the doped regions may be the same as the type of doping ions in the channel region. For example, a junctionless field effect transistor (JLT) may be formed.

Here, materials of the gate dielectric layer 114 may include, but are not limited to, silicon oxide, silicon nitride, or silicon oxynitride.

Illustratively, the silicon oxide may be formed on a substrate made from silicon by using a thermal oxidation process.

In some embodiments, the process for forming the gate dielectric layer 114 may include, but is not limited to, chemical vapor deposition (CVD), physical vapor deposition (PVD), atomic layer deposition (ALD), or any combination thereof.

Here, materials of the gate conductive layer 116 may include, but are not limited to, a metal material and a semiconductor material, where a metal material may be gold, aluminum, copper, tungsten, molybdenum, or the like, and the semiconductor material may be, for example, polysilicon.

In some embodiments, the process for forming the gate conductive layer 116 may include, but is not limited to, CVD, PVD, ALD, or any combination thereof.

In some embodiments, a work function of the first threshold voltage regulating layer 118 ranges from 4.6 eV to 6.9 eV. Optionally, the work function of the first threshold voltage regulating layer 118 ranges from 6 eV to 6.9 eV.

In the embodiments of the present disclosure, the first threshold voltage regulating layer 118 is disposed between the gate dielectric layer 114 and the gate conductive layer 116 in the gate structure 112, and the difference between the work functions of the gate structure 112 and the material of the channel region 110 is increased by increasing the work function of the first threshold voltage regulating layer 118, thereby increasing the threshold voltage of the transistor 102.

In some embodiments, a material of the first threshold voltage regulating layer 118 may be molybdenum trioxide (MoO3).

Here, molybdenum trioxide is an indirect bandgap material with a bandgap of about 3.0 eV, and it is also an excellent semiconductor oxide material with a high work function and the most stable oxide of molybdenum. Specifically, a work function of molybdenum trioxide may reach up to 6.9 eV.

Illustratively, molybdenum may be formed on the gate dielectric layer by using the ALD process and then oxidized multiple times by using oxygen (O2) or ozone (O3) to obtain molybdenum trioxide.

In some embodiments, a thickness of the first threshold voltage regulating layer 118 ranges from 0.25 nm to 4 nm.

Here, when the material of the first threshold voltage regulating layer 118 remains the same, the thickness is one of the factors that affect the work function of the first threshold voltage regulating layer 118.

Taking the example of molybdenum trioxide being the material of the first threshold voltage regulating layer 118 for illustration, as the thickness of the first threshold voltage regulating layer 118 increases, the work function of the first threshold voltage regulating layer 118 first increases and then remains substantially constant. When the thickness of the first threshold voltage regulating layer 118 is greater than 0.25 nm, the work function of the first threshold voltage regulating layer 118 is greater than 6.0 eV. However, as the thickness of the first threshold voltage regulating layer 118 increases, the size of the semiconductor device 100 becomes larger, which is not conducive to improving the integration density of the semiconductor device 100.

In the above embodiments, both high work function and high integration density can be achieved by limiting the thickness of the first threshold voltage regulating layer 118 to the range above.

In some embodiments, the transistor 102 includes a junctionless field effect transistor and a P-type transistor.

Here, since threshold voltages of the junctionless vertical channel transistor (VCT) and the P-type transistor are low, it is more necessary to improve structures of the junctionless vertical channel transistor and the P-type transistor and thereby to increase the threshold voltages thereof.

Referring to FIG. 2, FIG. 2 is a schematic cross-sectional structure diagram of a semiconductor device provided according to another example. As shown in FIG. 2, in some embodiments, the gate structure 112 further includes a second threshold voltage regulating layer 120 located between the first threshold voltage regulating layer 118 and the gate conductive layer 116, where a work function of the second threshold voltage regulating layer 120 is less than the work function of the first threshold voltage regulating layer 118.

In the embodiments of the present disclosure, the second threshold voltage regulating layer 120 is further disposed between the first threshold voltage regulating layer 118 and the gate conductive layer 116 in the gate structure 112, and the difference between the work functions of the gate structure 112 and the material of the channel region 110 is increased by increasing the work function of the second threshold voltage regulating layer 120 and using the high work functions of both the first threshold voltage regulating layer 118 and the second threshold voltage regulating layer 120, thereby increasing the threshold voltage of the transistor 102.

Furthermore, the work function of the second threshold voltage regulating layer 120 is less than the work function of the first threshold voltage regulating layer 118, and the second threshold voltage regulating layer 120 can not only increase the threshold voltage of the transistor 102 but also reduce a resistance of the gate structure 112.

In some embodiments, a material of the second threshold voltage regulating layer 120 may be molybdenum nitride.

Here, the work function varies depending on the nitrogen content in the molybdenum nitride. Compared to MON, the nitrogen content in Mo2N is lower and the work function of Mo2N is smaller; the work function of Mo2N is about 4.47 eV, and the work function of MoN is greater than 5 eV.

In some embodiments, the process for forming the second threshold voltage regulating layer 120 may include, but is not limited to, ALD.

In some embodiments, the first threshold voltage regulating layer 118 includes molybdenum trioxide, and/or the second threshold voltage regulating layer 120 includes molybdenum nitride, and/or the gate conductive layer 116 includes molybdenum.

Illustratively, molybdenum may be formed on the gate dielectric layer 114 by using the ALD process and then oxidized to form molybdenum trioxide, which serves as the first threshold voltage regulating layer 118; then, molybdenum nitride may be formed on the first threshold voltage regulating layer 118 by using the ALD process and serves as the second threshold voltage regulating layer 120; molybdenum may also grow as the gate conductive layer 116 on the second threshold voltage regulating layer 120 by still using the ALD process with the molybdenum nitride serving as a seed layer.

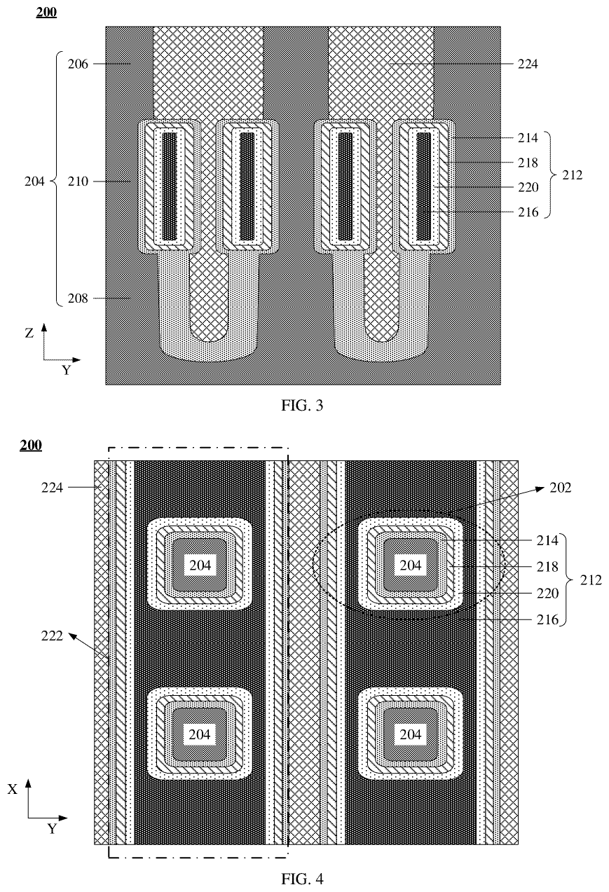

As described previously, the gate structure 112 provided in the embodiments of the present disclosure is particularly for vertical channel transistors and P-type transistors. Referring to FIGS. 3 and 4, FIG. 3 is a schematic cross-sectional structure diagram of a semiconductor device provided according to still another example, and FIG. 4 is a schematic top-view structure diagram of a semiconductor device provided according to still another example. Detailed description will be provided below by taking the example of the semiconductor device 200 being a vertical channel transistor 202 with reference to FIGS. 3 and 4.

Various directions of the semiconductor device are defined before the vertical channel transistor is introduced. The extension direction of a transistor pillar 204 in the vertical channel transistor 202 is defined as a third direction, i.e., a Z direction. A first direction and a second direction that intersect, i.e., an X direction and a Y direction, respectively, are defined in a plane perpendicular to the third direction Z. Alternatively, the semiconductor device 200 includes a plurality of transistors 202 arranged in an array, and the arrangement direction of the plurality of transistors 202 is defined as the first direction and the second direction that intersect, i.e., the X direction and the Y direction, respectively. In some embodiments, any two of the X direction, the Y direction, and the Z direction are perpendicular to each other.

In some embodiments, the semiconductor device 200 includes a plurality of transistors 202 arranged in an array along the first direction (i.e., the X direction) and the second direction (i.e., the Y direction). Each transistor 202 includes a transistor pillar 204 extending along the third direction (i.e., the Z direction).

FIG. 3 illustrates a YZ-plane cross-sectional view of the semiconductor device, and FIG. 4 illustrates an XY-plane top view of the semiconductor device. As shown in FIGS. 3 and 4, in some embodiments, the semiconductor device 200 includes at least one transistor 202 (as shown in a dashed circle in FIG. 4). Each transistor 202 includes a transistor pillar 204, and the transistor pillar 204 includes, in sequence along the extension direction, a first source/drain 206, a channel region 210, and a second source/drain 208; a gate structure 212 covers at least one sidewall of the transistor pillar 204.

In some embodiments, an orthographic projection of the transistor pillar on the XY plane may be quadrilateral, and the transistor pillar includes four sidewalls, where two sidewalls are oppositely disposed along the X direction, and the other two sidewalls are oppositely disposed along the Y direction. In other embodiments, an orthographic projection of the transistor pillar on the XY plane may also be circular, oval, and the like, and a shape of the orthographic projection of the transistor pillar on the XY plane is not particularly limited in the present disclosure.

In some embodiments, the gate structure covers one sidewall of the transistor pillar, i.e., a single-gate transistor is formed.

In some embodiments, the gate structure covers two sidewalls of the transistor pillar, i.e., a double-gate transistor is formed.

In some embodiments, the gate structure covers three sidewalls of the transistor pillar, i.e., a triple-gate transistor is formed.

In some embodiments, the gate structure covers four sidewalls of the transistor pillar, i.e., a gate-all-around transistor is formed. FIGS. 3 and 4 illustrate a gate-all-around transistor.

Here, the gate structure 212 includes, in sequence, a gate dielectric layer 214, a first threshold voltage regulating layer 218, a second threshold voltage regulating layer 220, and a gate conductive layer 216, where the gate dielectric layer 214 surrounds the channel region 210 of the transistor pillar 204, the first threshold voltage regulating layer 218 surrounds the gate dielectric layer 214, the second threshold voltage regulating layer 220 surrounds the first threshold voltage regulating layer 218, and the gate conductive layer 216 surrounds the second threshold voltage regulating layer 220.

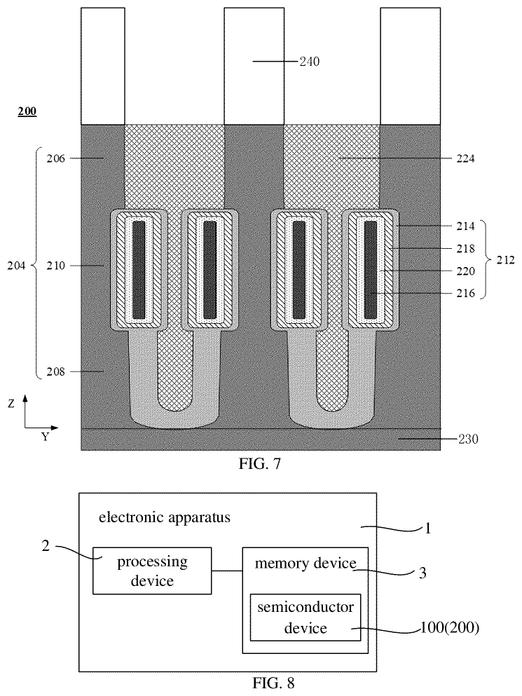

As shown in FIGS. 4 and 7, in some embodiments, the semiconductor device 200 further includes: a plurality of word lines 222 extending along the X direction (as shown in the dotted-dashed line box in FIG. 4), where each word line 222 is connected to gate structures 212 of a plurality of transistors 202 arranged along the X direction; a plurality of bit lines 230 extending along the Y direction, where each bit line is connected to a plurality of second sources/drains 208 arranged along the Y direction; and a plurality of storage capacitors 240, where each storage capacitor 240 is connected to a corresponding first source/drain 206.

Here, the semiconductor device includes the plurality of word lines 222 extending along the X direction and arranged in sequence along the Y direction and the plurality of bit lines 230 extending along the Y direction and arranged in sequence along the X direction, where adjacent word lines 222 are separated by a first isolation layer 224.

In some embodiments, when the transistor pillar includes, in sequence from top to bottom along the extension direction, the first source/drain 206, the channel region 210, and the second source/drain 208, a bit line connected to the first source/drain 206 may be formed on a front surface of the substrate, a back surface of the substrate may be thinned to expose the second source/drain 208, and a storage capacitor connected to the second source/drain 208 may be formed on the back surface of the substrate.

In other embodiments, for example, as shown in FIG. 7, when the transistor pillar includes, in sequence from top to bottom along the extension direction, the first source/drain 206, the channel region 210, and the second source/drain 208, a buried bit line connected to the second source/drain 208 may be formed on the front surface of the substrate, and a storage capacitor connected to the first source/drain 206 may be formed on the front surface of the substrate.

In other embodiments, when the transistor pillar includes, in sequence from top to bottom along the extension direction, the first source/drain 206, the channel region 210, and the second source/drain 208, a storage capacitor connected to the first source/drain 206 may be formed on the front surface of the substrate, the back surface of the substrate may be thinned to expose the second source/drain 208, and a bit line connected to the second source/drain 208 may be formed on the back surface of the substrate.

In some embodiments, a material of the bit line may include, but is not limited to, metals, metallic compounds, or alloys, where the metals may be copper, aluminum, tungsten, gold, silver, or the like; the metallic compounds may be, for example, tantalum nitride or titanium nitride; the alloys may be alloys formed of at least two metal elements of copper, aluminum, tungsten, gold, or silver.

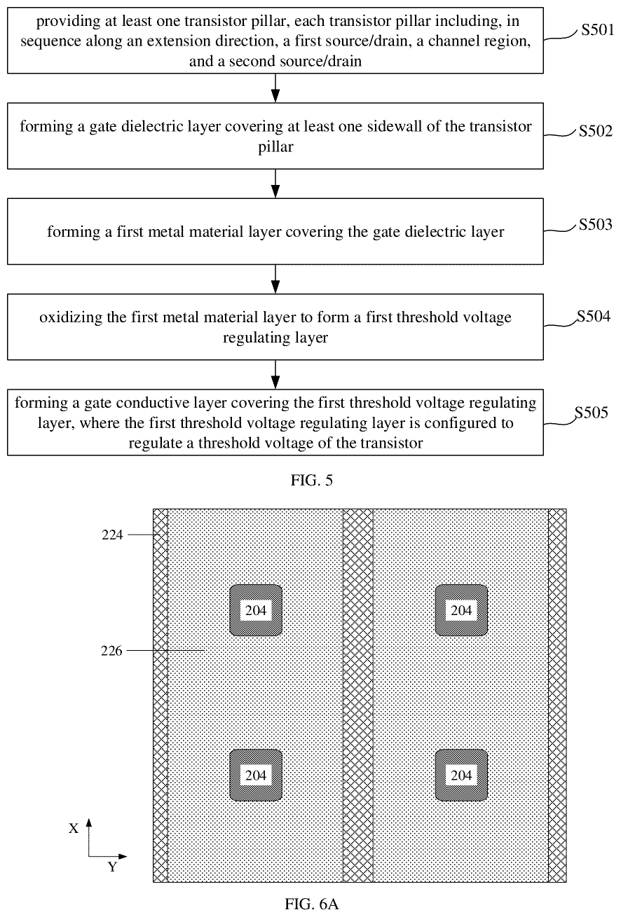

Referring to FIG. 5, FIG. 5 is a schematic flow chart of a method for manufacturing a semiconductor device provided according to the embodiments of the present disclosure. As shown in FIG. 5, the embodiments of the present disclosure further provide a method for manufacturing a semiconductor device. The semiconductor device includes at least one transistor, and the method includes:
Step S501: providing at least one transistor pillar, each transistor pillar including, in sequence along an extension direction, a first source/drain, a channel region, and a second source/drain;
Step S502: forming a gate dielectric layer covering at least one sidewall of the transistor pillar;
Step S503: forming a first metal material layer covering the gate dielectric layer;
Step S504: oxidizing the first metal material layer to form a first threshold voltage regulating layer;
Step S505: forming a gate conductive layer covering the first threshold voltage regulating layer, where the first threshold voltage regulating layer is configured to regulate a threshold voltage of the transistor.

In the embodiments of the present disclosure, the first threshold voltage regulating layer is disposed between the gate dielectric layer and the gate conductive layer, and a difference between work functions of the gate structure and a material of the channel region is increased by increasing a work function of the first threshold voltage regulating layer, thereby increasing the threshold voltage of the transistor, i.e., achieving the objective of improving electrical properties of the semiconductor device by using the first threshold voltage regulating layer to regulate the threshold voltage of the transistor.

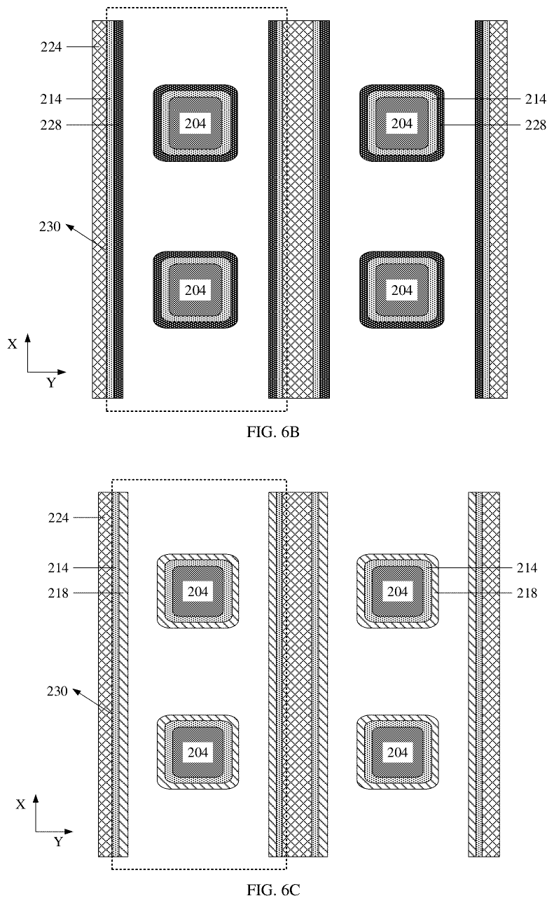

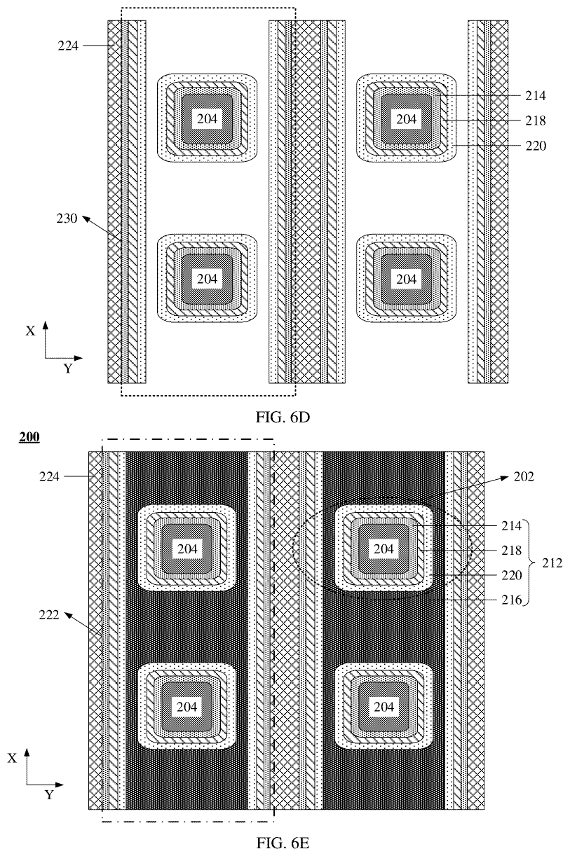

Referring to FIGS. 6A-6E, FIGS. 6A-6E are schematic top-view structure diagrams of a semiconductor device provided according to the embodiments of the present disclosure during a manufacturing process. The manufacturing process of the semiconductor device will be described in detail below with reference to FIG. 5 and FIGS. 6A-6E.

In the embodiments of the present disclosure, in step S501, at least one transistor pillar 204 is provided; each transistor pillar 204 includes, in sequence along an extension direction, a first source/drain 206, a channel region 210, and a second source/drain 208.

As shown in FIG. 6A, transistor pillars 204 arranged in an array along an X direction and a Y direction are formed on a substrate.

Illustratively, forming the transistor pillars 204 may include: providing a substrate; etching the substrate to form a plurality of first grooves extending along the Y direction and a plurality of semiconductor strips 204 extending along the Y direction, and filling the first grooves with isolation material; etching the substrate to form a plurality of second grooves extending along the X direction and a plurality of semiconductor pillars 204 (i.e., transistor pillars) arranged in an array along the X direction and the Y direction, and filling the second grooves with isolation material.

In some embodiments, after the semiconductor pillars 204 are formed, the semiconductor pillars 204 may also be doped to form doped regions (i.e., the first source/drain 206 and the second source/drain 208), and channel regions 210.

Illustratively, after the semiconductor pillars 204 are formed, the semiconductor pillars 204 may be doped by using an ion implantation or thermal diffusion process. Alternatively, after the substrate is doped, the substrate is etched to form a plurality of semiconductor pillars 204 arranged in an array, so that the semiconductor pillars 204 each have a channel region 210 and a first source/drain 206 and a second source/drain 208 located on two sides of the channel region 210, respectively.

As shown in FIG. 6A, in some embodiments, before the gate dielectric layer 214 is formed, the method further includes forming a first isolation layer 224 and a second isolation layer 226. The second isolation layer 226 is located between adjacent transistor pillars 204, and the first isolation layer 224 penetrates through the second isolation layer 226 located between the adjacent transistor pillars 204 along the X direction, where the first isolation layer 224 is configured to isolate adjacent word lines formed subsequently, so as to prevent electrical interference between adjacent conductive structures.

In some embodiments, materials of the first isolation layer 224 and the second isolation layer 226 may include, but are not limited to, silicon nitride.

In the embodiments of the present disclosure, in step S502, a gate dielectric layer 214 covering at least one sidewall of the transistor pillar 204 is formed.

As shown in FIG. 6B, the second isolation layer 226 is removed to form a word line recess 230 (as shown in the dashed box in FIG. 6B) exposing sidewalls of the transistor pillar 204; the gate dielectric layer 214 surrounding the sidewalls of the transistor pillar 204 and covering sidewalls of the word line recess 230 is formed.

Illustratively, silicon oxide may be formed to serve as the gate dielectric layer 214 by using an ALD process or an in-situ steam generation (ISSG) process.

In the embodiments of the present disclosure, in step S503, a first metal material layer 228 covering the gate dielectric layer 214 is formed.

As shown in FIG. 6B, the first metal material layer 228 surrounding the gate dielectric layer 214 on the sidewalls of the transistor pillar 204 and covering the sidewalls of the word line recess 230 is formed.

Illustratively, molybdenum may be formed to serve as the first metal material layer 228 by using an ALD process.

In the embodiments of the present disclosure, in step S504, the first metal material layer 228 is oxidized to form a first threshold voltage regulating layer 218.

As shown in FIG. 6C, the first metal material layer 228 is oxidized to form the first threshold voltage regulating layer 218, where the first threshold voltage regulating layer 218 surrounds the gate dielectric layer 214 on the sidewalls of the transistor pillar 204 and covers the sidewalls of the word line recess 230.

Illustratively, the first metal material layer 228, e.g., molybdenum, may be formed by using an ALD process; the first metal material layer 228 is oxidized by using oxygen or ozone to form the first threshold voltage regulating layer 218, e.g., molybdenum trioxide. The first metal material layer 228 may be formed multiple times and oxidized multiple times to form the first threshold voltage regulating layer 218.

In some embodiments, before step S505, the method further includes forming a second threshold voltage regulating layer 220 covering the first threshold voltage regulating layer 218, where a work function of the second threshold voltage regulating layer 220 is less than a work function of the first threshold voltage regulating layer 218.

As shown in FIG. 6D, the second threshold voltage regulating layer 220 surrounding the first threshold voltage regulating layer 218 on the sidewalls of the transistor pillar 204 and covering the sidewalls of the word line recess 230 is formed.

In the embodiments of the present disclosure, in step S505, a gate conductive layer 216 covering the first threshold voltage regulating layer 218 is formed, where the first threshold voltage regulating layer 218 is configured to regulate the threshold voltage of the transistor 202. Here, after the second threshold voltage regulating layer 220 is formed, the gate conductive layer 216 covering the second threshold voltage regulating layer 220 is formed.

As shown in FIG. 6E, the gate conductive layer 216 surrounding the second threshold voltage regulating layer 220 on the sidewalls of the transistor pillar 204 and covering the sidewalls of the word line recess 230 is formed, where the gate dielectric layer 214, the first threshold voltage regulating layer 218, the second threshold voltage regulating layer 220, and the gate conductive layer 216 surrounding the sidewalls of the transistor pillar 204 collectively form the gate structure 212.

Illustratively, the second threshold voltage regulating layer 220, e.g., molybdenum nitride, may be formed by using an ALD process; the gate conductive layer 216, e.g., molybdenum, is formed by growing with molybdenum nitride serving as a seed layer.

As shown in FIGS. 6E and 7, in the embodiments of the present disclosure, the method further includes: forming a plurality of word lines 222 extending along the X direction (as shown in the dotted-dashed line box in FIG. 6E), where each word line 222 is connected to gate structures 212 of a plurality of transistors 202 arranged along the X direction; forming a plurality of bit lines 230 extending along the Y direction, where each bit line 230 is connected to a plurality of second sources/drains 208 arranged along the Y direction; and forming a plurality of storage capacitors 240, where each storage capacitor 240 is connected to a corresponding first source/drain 206.

The embodiments of the present disclosure provide a semiconductor device and a manufacturing method therefor. The semiconductor device includes at least one transistor. Each transistor includes a first source/drain, a second source/drain, a channel region, and a gate structure. The channel region is located between the first source/drain and the second source/drain, and the gate structure includes a gate dielectric layer, a gate conductive layer, and a first threshold voltage regulating layer located between the gate dielectric layer and the gate conductive layer, where the gate dielectric layer is in contact with the channel region, and the first threshold voltage regulating layer is configured to regulate a threshold voltage of the transistor. In the embodiments of the present disclosure, the first threshold voltage regulating layer is disposed between the gate dielectric layer and the gate conductive layer, and a difference between work functions of the gate structure and a material of the channel region is increased by using the first threshold voltage regulating layer with a high work function, thus increasing the threshold voltage of the transistor and thereby improving the electrical properties of the semiconductor device by regulating the threshold voltage of the transistor.

It should be understood that reference throughout this specification to “one embodiment” or “an embodiment” means that a particular feature, structure, or characteristic described in connection with the embodiment is included in at least one embodiment of the present disclosure. Therefore, the appearances of the phrases “in one embodiment” or “in an embodiment” in various places throughout this specification do not necessarily all refer to the same embodiment. Furthermore, these particular features, structures, or characteristics may be combined in any suitable manner in one or more embodiments. It should be understood that, in various embodiments of the present disclosure, the sequence numbers of the processes described above do not imply an order of execution, and the order of execution of the processes should be determined by their functions and inherent logic, and these sequence numbers should not constitute any limitation to the implementation process of the embodiments of the present disclosure. The serial numbers of the embodiments of the present disclosure described above are for the purpose of describing only and do not represent the superiority or inferiority of the embodiments.

The foregoing only illustrates preferred embodiments of the present disclosure, but the patent scope of the present disclosure is not limited thereto; all equivalent structural changes made based on the content of the specification and drawings of the present disclosure or direct/indirect application in other related technical fields under the inventive concept of the present disclosure shall all fall within the patent protection scope of the present disclosure.

FIG. 8 is a schematic structure diagram of an electronic apparatus illustrated according to the embodiments of the present disclosure. Referring to FIG. 8, the embodiments of the present disclosure further provide an electronic apparatus 1. The electronic apparatus includes a processing device 2 and a memory device 3 electrically connected to the processing device 2, where the memory device 3 includes a semiconductor structure 300 shown in any one of the embodiments described above. The electronic apparatus 1 may be a terminal apparatus, e.g., a mobile phone, a tablet computer, a smart bracelet, a personal computer (PC), a server, a workstation, or the like. The memory function in the electronic apparatus 1 can be implemented by using the following memory devices 3: a dynamic random access memory (DRAM), a ferroelectric random access memory (FRAM), a phase change memory (PCM), a magnetic random access memory (MRAM), or a resistive random access memory (RRAM).

The above description is only the specific embodiments of the present disclosure, but the protection scope of the present disclosure is not limited thereto; changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

1. A semiconductor device, comprising at least one transistor, each transistor comprising a first source/drain, a second source/drain, a channel region, and a gate structure, wherein
the channel region is located between the first source/drain and the second source/drain;
the gate structure comprises a gate dielectric layer, a gate conductive layer, and a first threshold voltage regulating layer located between the gate dielectric layer and the gate conductive layer, wherein the gate dielectric layer is in contact with the channel region, and the first threshold voltage regulating layer is configured to regulate a threshold voltage of the transistor.

2. The semiconductor device according to claim 1, wherein the gate structure further comprises a second threshold voltage regulating layer located between the first threshold voltage regulating layer and the gate conductive layer, wherein a work function of the second threshold voltage regulating layer is less than a work function of the first threshold voltage regulating layer.

3. The semiconductor device according to claim 1, wherein each transistor comprises a transistor pillar, the transistor pillar comprising, in sequence along an extension direction, the first source/drain, the channel region, and the second source/drain;
the gate structure covers at least one sidewall of the transistor pillar.

4. The semiconductor device according to claim 3, wherein the semiconductor device comprises a plurality of transistors arranged in an array along a first direction and a second direction, each transistor comprising a transistor pillar extending along a third direction, wherein any two of the first direction, the second direction, and the third direction are perpendicular to each other; the semiconductor device further comprises:
a plurality of word lines extending along the first direction, each word line being connected to gate structures of a plurality of transistors arranged along the first direction;
a plurality of bit lines extending along the second direction, each bit line being connected to a plurality of second sources/drains arranged along the second direction; and
a plurality of storage capacitors, each storage capacitor being connected to a corresponding first source/drain.

5. The semiconductor device according to claim 1, wherein a work function of the first threshold voltage regulating layer ranges from 4.6 eV to 6.9 eV.

6. The semiconductor device according to claim 1, wherein a thickness of the first threshold voltage regulating layer ranges from 0.25 nm to 4 nm.

7. The semiconductor device according to claim 1, wherein the transistor is a junctionless field effect transistor or a P-type transistor.

8. The semiconductor device according to claim 2, wherein the first threshold voltage regulating layer comprises molybdenum trioxide, and/or the second threshold voltage regulating layer comprises molybdenum nitride, and/or the gate conductive layer comprises molybdenum.

9. The semiconductor device according to claim 1, wherein the first threshold voltage regulating layer is molybdenum trioxide; the gate conductive layer is molybdenum.

10. The semiconductor device according to claim 2, wherein the gate structure covers four sidewalls of the transistor pillar to form a gate-all-around transistor, wherein,
the gate dielectric layer surrounds the channel region of the transistor pillar, the first threshold voltage regulating layer surrounds the gate dielectric layer, the second threshold voltage regulating layer surrounds the first threshold voltage regulating layer, and the gate conductive layer surrounds the second threshold voltage regulating layer.

11. A method for manufacturing a semiconductor device, the semiconductor device comprising at least one transistor, the method comprising:
providing at least one transistor pillar, each transistor pillar comprising, in sequence along an extension direction, a first source/drain, a channel region, and a second source/drain;
forming a gate dielectric layer covering at least one sidewall of the transistor pillar;
forming a first metal material layer covering the gate dielectric layer;
oxidizing the first metal material layer to form a first threshold voltage regulating layer; and
forming a gate conductive layer covering the first threshold voltage regulating layer, wherein the first threshold voltage regulating layer is configured to regulate a threshold voltage of the transistor.

12. The method for manufacturing a semiconductor device according to claim 11, wherein before the gate conductive layer covering the first threshold voltage regulating layer is formed, the method further comprises:
forming a second threshold voltage regulating layer covering the first threshold voltage regulating layer, wherein a work function of the second threshold voltage regulating layer is less than a work function of the first threshold voltage regulating layer.

13. The method for manufacturing a semiconductor device according to claim 12, wherein a material of the second threshold voltage regulating layer is molybdenum nitride.

14. The method for manufacturing a semiconductor device according to claim 11, wherein the first metal material layer is molybdenum, and the first threshold voltage regulating layer is molybdenum trioxide, wherein the step of oxidizing the first metal material layer to form the first threshold voltage regulating layer comprises:
oxidizing the molybdenum multiple times by using oxygen or ozone to obtain the molybdenum trioxide.

15. The method for manufacturing a semiconductor device according to claim 14, wherein a thickness of the first threshold voltage regulating layer ranges from 0.25 nm to 4 nm.

16. The method for manufacturing a semiconductor device according to claim 13, wherein the step of forming the gate conductive layer comprises:
growing molybdenum as the gate conductive layer on the second threshold voltage regulating layer by using an ALD process with the molybdenum nitride serving as a seed layer.

17. The method for manufacturing a semiconductor device according to claim 11, wherein the transistor is a junctionless field effect transistor or a P-type transistor.

18. The method for manufacturing a semiconductor device according to claim 11, wherein before the step of forming the gate dielectric layer covering at least one sidewall of the transistor pillar, the method further comprises:
forming a first isolation layer and a second isolation layer, the second isolation layer being located between adjacent transistor pillars, and the first isolation layer penetrating through the second isolation layer located between the adjacent transistor pillars along a first direction.

19. The method for manufacturing a semiconductor device according to claim 11, wherein a gate structure covers four sidewalls of the transistor pillar to form a gate-all-around transistor, wherein,
the gate dielectric layer surrounds the channel region of the transistor pillar, the first threshold voltage regulating layer surrounds the gate dielectric layer, a second threshold voltage regulating layer surrounds the first threshold voltage regulating layer, and the gate conductive layer surrounds the second threshold voltage regulating layer.

20. An electronic apparatus, comprising:
a processing device; and
a memory device electrically connected to the processing device, the memory device comprising the semiconductor device according to claim 1.
